(19) United States
(12) Patent Application Publication
(10) Pub. No.: US 2007/0248515 A1
(43) Pub. Date: Oct. 25, 2007

(54) System and Method for Forming Multi-Component Films

(76) Inventors: Gary S. Tompa, Belle Mead, NJ (US); Catherine E. Rice, Scotch Palins, NJ (US); Nick M. Sbrockey, Gaithersburg, MD (US); Brent H. Hoerman, New Brunswick, NJ (US); Lloyd G. Provost, Glen Ridge, NJ (US); Sun Shangzhu, Hillsborough, NJ (US)

Correspondence Address: PATENT DOCKET ADMINISTRATOR;LOWENSTEIN SANDLER PC, 65 LIVINGSTON AVENUE, ROSELAND, NJ, 07068, US

(21) Appl. No.: 10/580,771

(22) PCT Filed: Dec. 1, 2004
(86) PCT No.: PCT/US04/40074

§ 371 Date: Mar. 8, 2007

Related U.S. Application Data
(60) Provisional application No. 60/525,741, filed on Dec. 1, 2003.

(51) Int. Cl. C01D 15/00; B05D 3/12; C23C 16/00

(52) U.S. Cl. 423/179; 118/719; 118/726; 427/248.1

(57) ABSTRACT

A system and a method for depositing films of a multi-component material by MOCVD utilizes a flash evaporator for providing vaporized reactant material at a high flow rate. The high flow rate enables film deposition to occur at a higher deposition rate that what is possible with conventional MOCVD systems. The system may be a single-chamber system or part of a multiple-chamber system. The multiple-chamber system allows multi-layer structures to be deposited and/or processed in situ.

### CROSS REFERENCE TO RELATED APPLICATIONS

This application claims benefit of U.S. Provisional Patent Application No. 60/525,741 filed on Dec. 1, 2003, the entire disclosure of which is incorporated herein by reference.

### STATEMENT REGARDING FEDERALLY SPONSORED RESEARCH OR DEVELOPMENT

The present invention was made with support from the U.S. Government under Contract No. F49620-02-C-0079 and Contract No. FA9550-04-C-0017, both awarded by the Missile Defense Agency of the Air Force, and under Grant No. DMI-0320135 from the National Science Foundation. The U.S. Government has certain rights in this invention.

### BACKGROUND OF THE INVENTION

1. Field of the Invention

The present invention relates generally to a system and a method for depositing films of a multi-component material such as, for example, a multi-component metal oxide. More particularly, the present invention relates to a chemical vapor deposition (CVD) system and a method of using the CVD system for depositing films of a lithium-niobium-oxygen material such as, for example, lithium niobate (LiNbO₃); films of a zinc-magnesium-oxygen material such as, for example, Zn₁₋ₓMgₓO; and films of zinc oxide (ZnO). However, the present invention is not limited to depositing only metal-oxide films, but extends to other materials systems including carbides, nitrides, silicides, III-V compounds, II-VI compounds, organics, polymers, and so on.

2. Related Art

Optical communications plays a significant role in modern communications technology. Optical signals have the potential to transmit a larger quantity of information than conventional electrical signals. That is, the transmission rate (bits/second) of optical signals can be greater than that the transmission rate of conventional electrical signals.

Conventional electro-optical switches and modulators currently used in optical communications are based on bulk crystals of LiNbO₃. A dopant species, typically titanium (Ti), is diffused into the crystal to alter its optical characteristics and thus define a waveguide layer. One problem with diffusing Ti into bulk LiNbO₃ is that the resulting concentration profile of Ti in the waveguide layer takes the shape of a typical error-function diffusion profile, in which the Ti concentration varies with distance from the surface of the LiNbO₃. Therefore, if standard diffusion techniques are used to dope the waveguide layer, only graded-index waveguides can be produced. As a consequence, devices with diffused waveguide layers have mode profiles that are poorly optimized for electro-optical functions. Further, diffused waveguide layers provide only weak confinement of optical signals and therefore such layers effectively are precluded from being used in densely integrated circuits, which require serpentine structures having small radii of curvature. These shortcomings cause devices made from bulk LiNbO₃ and having diffused waveguide layers to be large and slow, and to require high operating voltages.

Another issue with the use of bulk LiNbO₃ is that the Li/Nb stoichiometry of the bulk material is based on its congruent melting composition. The congruent melting composition, however, may not be the best composition for producing devices with optimal electro-optical characteristics. The limited ability to vary the Li/Nb stoichiometry in bulk LiNbO₃ is a factor that limits the quality of devices made from bulk LiNbO₃. Stoichiometric LiNbO₃ is advantageous due to its higher electro-optic coefficients over congruent-melting (Li₂O deficient) LiNbO₃.

Yet another issue with the use of bulk LiNbO₃ is the presence of iron (Fe) in the bulk material, which degrades its optical characteristics.

Advances in thin-film technology have led to attempts to form LiNbO₃ films for use in electro-optical devices. Films of uniformly doped LiNbO₃ would allow the fabrication of step-index waveguides, in which the index of refraction changes abruptly at the interface of the doped film in comparison with the gradual change in the index of refraction in graded-index waveguides. This would permit the fabrication of engineered layered structures with indices of refraction selectively and specifically tailored for particular applications. Additionally, this would enable LiNbO₃-based devices to be more compact, with consequent lower signal losses, higher speeds, lower operating voltages, and a greater degree of device integration. Further, thin-film technology has the potential to produce lithium niobate films with a stoichiometry tailored to be optimal for a particular application. That is, the lithium niobate films are not limited to the congruent melting composition typical of bulk LiNbO₃.

Techniques such as sputtering, laser ablation, sol-gel, thermal-plasma spray CVD, liquid-phase epitaxy (LPE), chemical-beam epitaxy, and metal-organic CVD (MOCVD) have been used in an effort to form high-quality epitaxial LiNbO₃ films suitable for electro-optical devices. In general, LiNbO₃ films formed by these techniques suffer from being too thin and from having excessive optical losses.

For effective waveguiding, the film thickness should be on the order of the communication wavelength, which presently is about 1.55 μn. Epitaxial LiNbO₃ films have been deposited on sapphire substrates up to a thickness of only about 2000 Å, due to cracking caused by the large thermal-expansion mismatch between the film and the substrate. Lithium tantalate (LiTaO₃) substrates have a better thermal-expansion match with LiNbO₃, but have not yielded films greater than 6000 Å in thickness.

Effective waveguiding also requires LiNbO₃ films that are able to transmit optical signals with a very low loss in signal strength. Nominally, losses of less than 0.2 dB/cm are preferred. Typical sources of optical losses in LiNbO₃ films include: impurities (e.g., Fe impurities cause photorefractive effects); film defects; surface roughness; low oxygen stoichiometry; and crystalline inhomogeneities.

In order to be commercially viable, not only do LiNbO₃ films have to be of a sufficient thickness and a sufficiently high quality, the films also have to be formed efficiently and uniformly. That is, the deposition rate should be high enough such that films can be produced economically, and each film should be uniform in quality and thickness over its entire area and from film to film.

### SUMMARY OF INVENTION

The present invention relates to a system and a method for forming multi-component films at a high deposition rate.

According to the invention, the system is a flash MOCVD system, which includes a flash evaporator for providing a reactant gas at a high flow rate. The system also includes a gas distribution system that improves the uniformity of a deposited film by distributing the reactant gas according to a zone arrangement, such that the quantity of reactive gas distributed to each zone is the same, approximately the same, or may be individually controlled.

According to an aspect of the invention, the flash MOCVD system is incorporated in a multi-chamber vacuum deposition system, in which each chamber is connected to a load-lock station that functions to transfer substrates from chamber to chamber without exposing the substrates to atmospheric pressure and without cross-contaminating any of the chambers with material from another chamber. The flash MOCVD system is incorporated as one of the chambers of multi-chamber vacuum deposition system. The other chambers of the multi-chamber vacuum deposition system may include, for example, an annealing system, a plasma treatment system, an etching system, and other film deposition systems, as well as any other type of film processing system. Optionally, the multi-chamber vacuum deposition system may include more than one flash MOCVD system. Each chamber may be isolated from the other chambers.

According to another aspect of the invention, the method utilizes a flash MOCVD system to produce crack-free lithium niobate films greater than 1.5 μm thick at deposition rates greater than 3.0 μ/h.

According to yet another aspect of the invention, the method utilizes a flash MOCVD system to produce a pn-junction of p-type ZnO and n-type ZnO in situ.

According to another aspect of the present invention, a multiple-chamber film processing system is used to form a multi-layer structure. The multiple chambers may include any or all of a sputtering system, an evaporation system, a molecular-beam epitaxy system, a CVD system, an annealing system, a plasma treatment system, an etching system, and a flash MOCVD system. The multiple chambers are interconnected via a load-lock system. Each of the multiple chambers may be isolated from the other chambers.

According to yet another aspect of the invention, the method utilizes a multiple-chamber film processing system, such as the one described above, to produce a multi-layer structure with at least two layers being formed in different chambers of the system, and without exposing an interlayer interface to atmospheric conditions. As an example, one of the layers may be a passivation layer. As another example, one of the layers may be a metallization layer.

According to another aspect of the invention, the method utilizes a multiple-chamber film processing system, such as the one described above, to produce a multi-layer structure in which a first layer is formed in a first chamber, the first layer undergoes treatment in a second chamber, and a second layer is formed in the first chamber or in a third chamber. An interface between the first and second layers is not exposed to atmospheric conditions before the second layer is formed. The treatment may be, for example, an annealing process, a plasma-treatment process, and the like, Optionally, the multi-layer structure undergoes treatment in the second chamber or in another chamber before the multi-layer structure is exposed to atmospheric conditions.

According to a further aspect of the invention, the method utilizes a multiple-chamber film processing system, such as the one described above, to produce a pn-junction of p-type ZnO and n-type ZnO in situ. Each ZnO layer of the pn-junction may but need not be formed using a respective flash MOCVD system.

### BRIEF DESCRIPTION OF THE DRAWINGS

The present invention will be more readily understood from the detailed description of preferred embodiments presented below considered in conjunction with the attached drawings, of which:

FIG. 1A is schematic diagram showing an arrangement of a deposition system, which may form a portion of a larger multi-chamber system, according to an embodiment of the present invention;

FIG. 1B shows a block diagram of selected features of the deposition system of FIG. 1A;

FIG. 2 is a block diagram of an arrangement of a flash evaporator, according to an embodiment of the present invention;

FIG. 3 schematically shows an arrangement of a reaction chamber, a gas distribution system, a substrate holder/heater assembly, and a vacuum assembly, according to an embodiment of the present invention;

FIGS. 4A, 4B, and 4C each schematically show an arrangement of the gas distribution system;

FIG. 5 schematically shows an exploded view of a portion of the gas distribution system;

FIG. 6 schematically shows a plan view of a zone-distribution section of the gas distribution system;

FIGS. 7A and 7B depict pipe arrangements for a cooling section of the gas distribution system;

FIGS. 8A and 8B each schematically illustrate an arrangement of a flow homogenizer in an overlaid representation with respect to the zone-distribution section, according to embodiments of the present invention;

FIG. 9 schematically shows a plan view of an alternative zone-distribution section of the gas distribution system;

FIG. 10 is a graph showing how the deposition rate of lithium niobate varies as a function of the deposition (substrate) temperature, for a given precursor-cocktail flow rate;

FIG. 11 is a schematic diagram showing an arrangement for a single-chamber system for depositing ZnO, according to an embodiment of the present invention;

FIG. 12A is a schematic diagram showing an arrangement of a multiple-chamber deposition system, according to an embodiment of the present invention;

FIG. 12B shows a block diagram of selected features of the multiple-chamber deposition system of FIG. 12A;

FIG. 13 is a schematic diagram of cluster configuration of a multiple-chamber deposition system, according to an embodiment of the present invention; and

FIG. 14 is a schematic diagram showing an arrangement of an ultrasonic vaporizer, according to an embodiment of the present invention.

It is to be understood that the attached drawings generally are schematic and not drawn to scale.

### DETAILED DESCRIPTION OF THE INVENTION

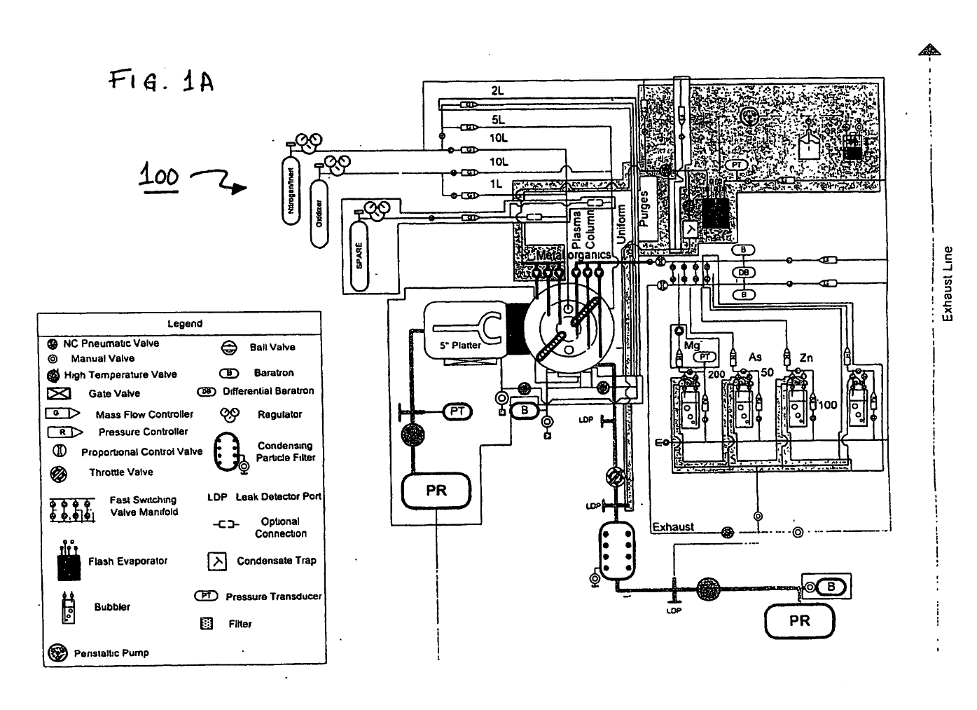

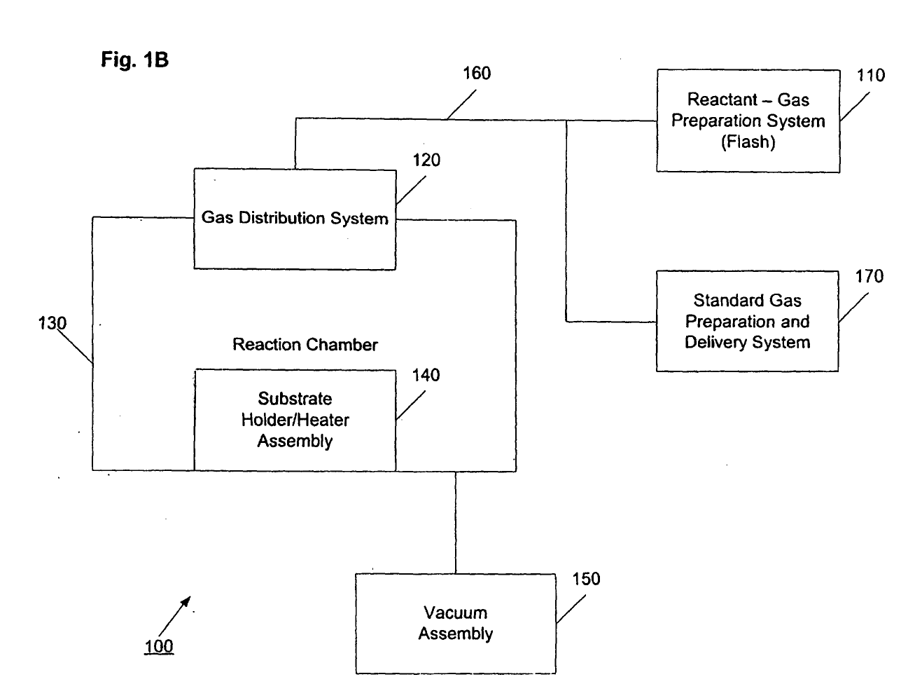

FIG. 1A schematically shows a flash MOCVD system 100 according to an embodiment of the present invention, and FIG. 1B shows a block diagram of selected features of the deposition system 100.

The flash MOCVD system 100 includes a reactant-gas preparation system 110, a gas distribution system 120, a reaction chamber 130, a substrate holder/heater assembly 140, and a vacuum assembly 150. Optionally, the deposition system also includes a standard gas preparation and delivery system 170. It should be understood that the delivery lines connecting the various elements in FIGS. 1A and in 1B represent fluid (gas and/or liquid) delivery conduits of any known type including, but not limited to, copper tubing, stainless-steel tubing, and Teflon tubing, etc.

The flash MOCVD system 100 performs MOCVD of multi-component films such as, for example, metals, oxides, nitrides, carbides, silicides, oxy-nitrides, and alloys thereof. According to a preferred embodiment, the flash MOCVD system 100 performs MOCVD of oxides such as, for example, niobates, titanates, tantalates, and zinc.

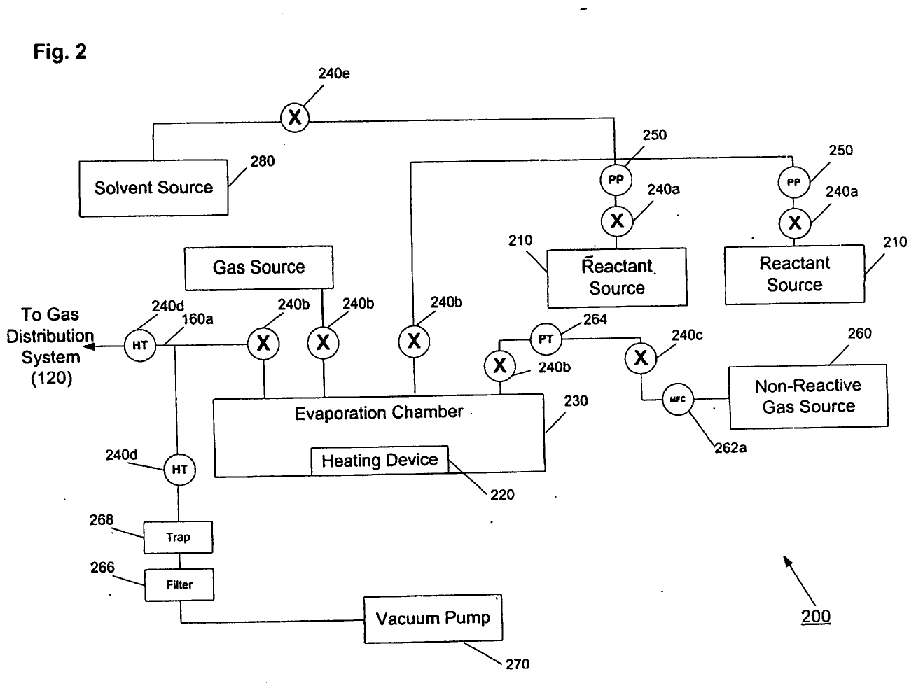

The reactant-gas preparation system 110 provides reactant gases to the reaction chamber 130 via the gas distribution system 120. Preferably, the reactant-gas preparation system 110 is a flash evaporator 200, as schematically shown in FIG. 2, according to an embodiment of the present invention.

The flash evaporator 200 includes at least one reactant-source vessel 210 containing a reactant material. Preferably, the reactant material is in liquid form, and preferably the vessel 210 is sealed from atmosphere. For a liquid reactant material, a pump 250 may be used to cause the liquid to flow from the vessel 210 towards an evaporation chamber 230. The pump 250 may be any known type of pump for pumping liquid. Preferably, the pump 250 is a peristaltic pump. A valve 240a is located between the vessel 210 and the pump 250 to enable the vessel 210 to be selectively isolated from the rest of the flash evaporator 200. Similarly, a valve 240b is located at each inlet and each outlet of the evaporation chamber 230 to enable the evaporation chamber to be selectively isolated from the rest of the flash evaporator 200.

The walls of the vessel 210 are maintained at a predetermined temperature to prevent condensation of vapors thereon. Preferably, the temperature of the walls is sufficiently high to prevent condensation, but not high enough to promote premature decomposition of the reactant material. As discussed in more detail below, the reactant material may include one or more precursor materials from which a reactant gas is produced. The walls may be naturally heated by heat from a heating device 220 during vaporization of the reactant material, or the walls may be intentionally heated using an external heater (not shown) or intentionally cooled an external cooler (not shown).

The flash evaporator 200 includes a source of non-reactive gas 260 for diluting and/or pushing the vaporized reactant material and/or for flushing the evaporation chamber 230. The non-reactive gas may be, for example, nitrogen, an inert gas, or a combination thereof. Optionally, a source of reactive gas (not shown) may be advantageously used to add an amount of reactive gas to the flash evaporator 200.

A mass-flow controller 262a controls the flow of the non-reactive gas to the evaporation chamber 230, and a pressure transducer 264 measures the pressure within the evaporation chamber 230. Preferably, the pressure transducer 264 and the mass-flow controller 262a are electrically connected such that the mass-flow controller 262a adjusts automatically according to a signal from the pressure transducer 264 to maintain a constant pressure in the evaporation chamber 230 during operation. A valve 240c is located between the pressure transducer 264 and the mass-flow controller 262a to enable the source of non-reactive gas 260 and the mass-flow controller 262a to be selectively isolated from the rest of the flash evaporator 200.

Optionally, the valve 240b positioned at the outlet of the evaporation chamber 230, between the evaporation chamber 230 and the valve 240d, is a variable orifice that functions to control the pressure within the evaporation chamber 230 as well as the flow of gases out of the evaporation chamber 230.

The evaporation chamber 230 is connected to a vacuum pump 270, which evacuates the evaporation chamber 230 to remove unwanted background gases prior to vaporization of the reactant material. Preferably, the evaporation chamber 230 is kept under a vacuum even when not in use, to prevent water vapor or other contaminants from condensing or collecting on its internal surfaces. A valve 240d is positioned between the evaporation chamber 230 and the vacuum pump 270, and functions to, for example, isolate the vacuum pump 270 from the rest of the flash evaporator 200. Preferably, the valve 240d is a high-temperature valve. Optionally, a particle filter 266 and/or a condensate trap 268 are installed between the vacuum pump 270 and the evaporation chamber 230 to protect the vacuum pump 270 from solids and/or liquids.

The heating device 220 located in the evaporation chamber 230 provides heat for vaporizing the reactant material to form a reactant gas, which constitutes at least part of the deposition gas used for forming a film. Heating may be accomplished by any known heating method, including radiative heating, resistive heating, and inductive heating, for example. The heating device 220 may be a wire, a cup-like container, a dish-like container, and a plate, for example. According to a preferred embodiment, the heating device 220 is a stainless steel plate heated by one or more resistive heaters (not shown).

The reactant gas and any push gas or other gas used during vaporization of the reactant material exits the evaporation chamber 230 via a conduit 160a of a conduit assembly 160, which delivers the gas(es) to the gas distribution system 120. A valve 240d is positioned between the gas distribution system 120 and the evaporation chamber 230. Preferably, the valve 240d is a high-temperature valve and functions to isolate the gas distribution system 120 from the evaporation chamber 230.

A solvent source 280 provides a solvent for cleaning the delivery lines to the heating device 220 and for cleaning the heating device 220 itself prior to film deposition. The solvent is vaporized by the heating device 220, and the vaporized solvent is vented from the flash evaporator 200 through the vacuum pump 270. A valve 240e is positioned in the delivery line of the solvent source 280 functions to isolate the solvent source 280 from the rest of the flash evaporator 200. The solvent may be, for example, toluene, although any other solvent compatible with the reactant material and easily volatilized may be used.

The flash evaporator 200 of the present invention functions to quickly and efficiently vaporize the reactant material to form the reactant gas. This allows the supply rate of the reactant gas to be greater than that achievable using conventional reactant-gas sources such as, for example, bubblers. Additionally, the flash evaporator 200 provides the reactant gas at a steadier flow rate than conventional bubblers. That is, when a bubbler is used to evaporate a solid material, the solid material can have a surface area that varies with time and thus will have an evaporation rate that varies with time. This causes the delivery rate of the vaporized material to vary with time. Another issue with conventional reactant-gas sources is that some reactant materials must be maintained at a temperature above where decomposition begins, which may lead to variations in the amount of reactant gas being outputted and also may lead to the formation of undesirable byproducts.

In contrast, the flash evaporator 200 has a delivery rate that is determined by the rate of introduction (feed rate) of the reactant material to the heating device 220, which is easily controlled by the pump 250 and which minimizes the amount of time the reactant material is spent at a temperature above the decomposition temperature. As a consequence, films formed by MOCVD using the flash evaporator 200 have a higher, more uniform, and more predictable deposition rate that films formed by conventional MOCVD (i.e., without using the flash evaporator 200).

The standard gas preparation and delivery system 170 is a system for delivering reactant gases as well as non-reactive gases by conventional techniques, including bubblers and direct gas sources, for example.

Optionally, the flash evaporator 200 may be an ultrasonic flash evaporator 1400, an arrangement of which is schematically shown in FIG. 14. The ultrasonic flash evaporator 1400 includes an inlet port 1410, a nozzle body 1420, and a nozzle stem 1430. Liquid reactant material enters the ultrasonic flash evaporator 1400 through the inlet port 1410 and travels through a conduit 1440 in the nozzle body 1420. The reactant material then passes through the nozzle stem 1430 and exits out of an outlet port 1450 in the nozzle stem 1430. Ultrasonic waves from a generator (not shown) are launched through the nozzle body 1420 and focused in a region (focus region) below the nozzle stem 1430. The reactant material exiting the outlet port 1450 and traveling through the focus region is vaporized by the focused ultrasonic waves to form the reactant gas.

Preferably, the ultrasonic flash evaporator 1400 has an upper (cool) zone 1460, which is cooled by a cooling gas delivered through an inlet port 1462 to cool the nozzle body 1420. A thermocouple monitors the temperature of the nozzle body 1420 to ensure that the temperature does not exceed or closely approach the Curie point of piezoelectric material in the nozzle. Excessive heating near or above the Curie point causes the vaporization efficiency of the ultrasonic flash evaporator 1400 to diminish.

Preferably, the ultrasonic flash evaporator 1400 has a lower (hot) zone 1470, which is heated by a hot gas delivered through an inlet port 1472. The hot gas heats the nozzle stem 1430 to prevent water vapor or other liquids from condensing thereon. Of course, heating by the hot gas does not cause the temperature of the nozzle stem 1430 to exceed or closely approach the Curie point of the piezoelectric material. As shown in FIG. 14, the hot gas also serves as a push gas. Optionally, an intermediate (warm) zone (not shown) of the ultrasonic flash evaporator 1400 may be heated by a warm gas to provide a transition from the cool zone 1460 to the hot zone 1470.

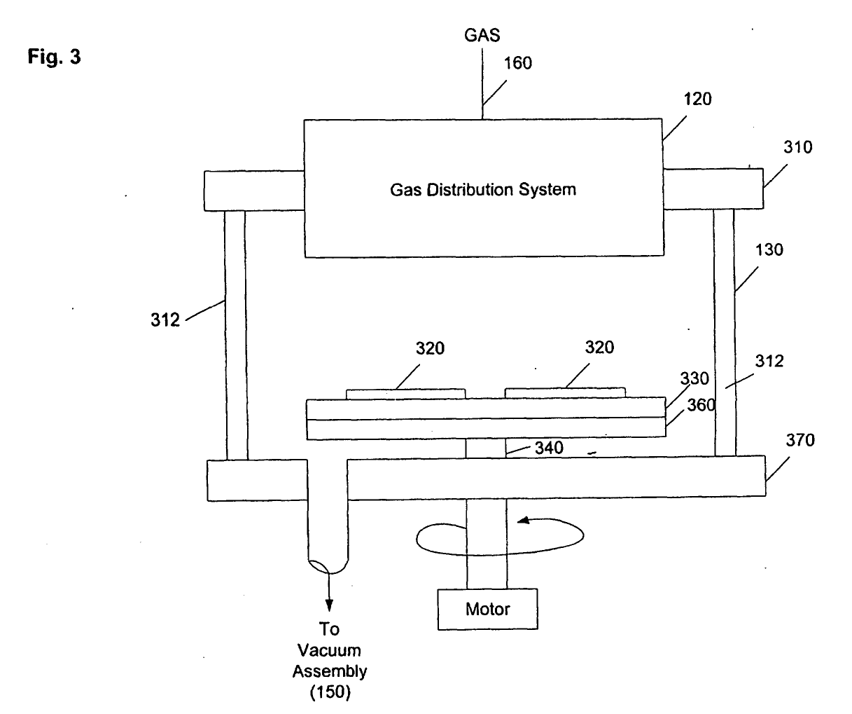

FIG. 3 is a diagram schematically showing an arrangement of the reaction chamber 130, the gas distribution system 120, the substrate holder/heater assembly 140, and the vacuum assembly 150, according to an embodiment of the present invention. The reaction chamber 130 is kept under a vacuum by the vacuum assembly 150 to prevent water vapor or other contaminants from condensing or collecting on its internal surfaces. The vacuum assembly 150 also functions to maintain the reaction chamber 130 at a controlled sub-atmospheric pressure during film deposition, through use of a throttle valve (not shown), for example. Preferably, the reaction chamber 130 is made of stainless steel. The gas distribution system 120, which is discussed in detail below, extends through a top plate 310 of the reaction chamber 130 and functions to distribute the deposition gas supplied by the conduit assembly 160 over one or more substrates 320 mounted on the substrate holder/heater assembly 140. The deposition gas includes the reactant gas produced by the flash evaporator 200, and optionally may include an inert carrier gas and/or one or more gases provided by the standard gas preparation and delivery system 170. For example, oxygen may be provided by the standard gas preparation and delivery system 170.

Although FIG. 3 shows the position of an exhaust port to the vacuum assembly 150 to be at a non-central location with respect to the reaction chamber 130, one of ordinary skill in the art will appreciate that it is preferable to have the exhaust port to be concentric with the substrate holder/heater assembly 140. Alternatively, any vacuum exhaust arrangement that does not disturb a uniform flow of the deposition gas over the substrate 320 may be used.

Preferably, the reaction chamber 130 is thermally isolated from its surroundings through contact with an isothermal fluid flowing along a side wall 312 of the reaction chamber 130. The isothermal fluid may flow, for example, in a coiled tube (not shown) wrapped along the side wall 312. Alternatively, the side wall 312 may be a double-walled structure that allows the isothermal fluid to flow within a fluid-tight cavity. Of course, other methods may be used to control the temperature of the surfaces of the reaction chamber 130. By maintaining the temperature of the side wall 312 to be above the condensation temperature and below the decomposition temperature of any constituent of the deposition gas, the composition and growth rate of the deposited films are controlled.

The substrate holder/heater assembly 140 is supported by a bottom plate 370 of the reaction chamber 130. The substrate holder/heater assembly 140 includes a rotatable susceptor 330, on which is mounted at least one substrate 320. The susceptor 330 is rotated through a shaft 340, which extends through the bottom plate 370, by a motor 350 mounted externally from the reaction chamber 130. A heater 360 is positioned below the susceptor 330 and functions to heat the susceptor 330, which in turn heats the substrate 320. Heating may be accomplished by any known heating method, including radiative heating, resistive heating, and inductive heating, for example. Optionally, for some deposition processes, such as for the deposition of organic or polymeric materials, the heater 360 may be replaced with a cooling device (not shown). An optical pyrometer (not shown) may be used to measure the surface temperature of the substrate 320.

During MOCVD of a film, the deposition gas distributed by the gas distribution system 120 flows over the substrate 320, where the reactant gas decomposes (and in some cases interacts with another gas of the deposition gas) to form (deposit) the film. The vacuum assembly 150 removes gaseous reaction products and any unused gas(es) from the reaction chamber 130. Vacuum technology is well developed, and the vacuum assembly 150 includes one or more vacuum pumps and associated valves and plumbing hardware arranged in any known manner for evacuating the reaction chamber 130 and maintaining a controlled sub-atmospheric pressure during film deposition. As mentioned above, the vacuum assembly 150 functions to maintain a vacuum within the reaction chamber 130 to prevent water vapor or other contaminants from condensing or collecting on its internal surfaces and subsequently affecting film properties.

Although FIG. 1B shows only a single reactant-gas preparation system 110 (or flash evaporator 200) connected to the gas distribution system 120 via the conduit assembly 160, the flash MOCVD system 100 may include more than one reactant gas preparation system 110 (or flash evaporators 200) connected to the gas distribution system 120 via the conduit assembly 160. That is, the flash MOCVD system 100 may include multiple flash evaporators 200 for separately vaporizing different reactant materials and separately delivering different reactive gases to the gas distribution system 120. Such an arrangement prevents premature reaction of the different reactive gases with each other.

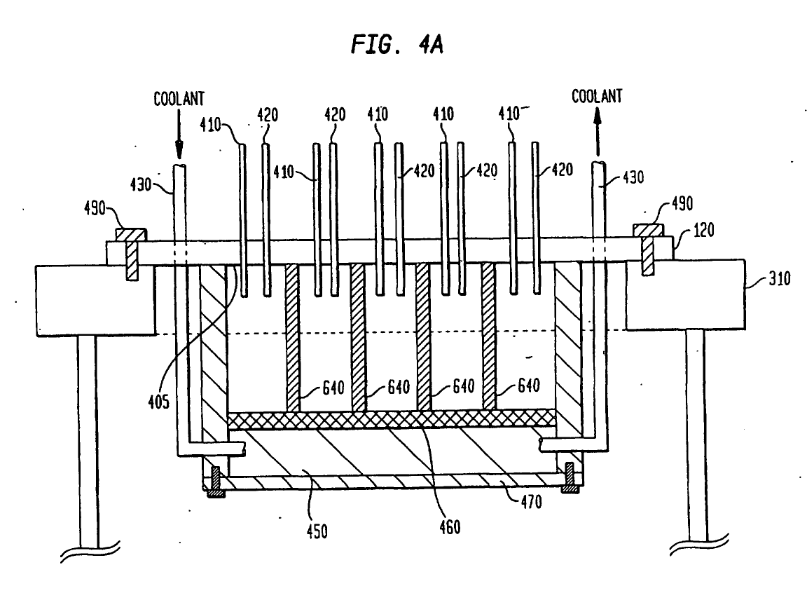

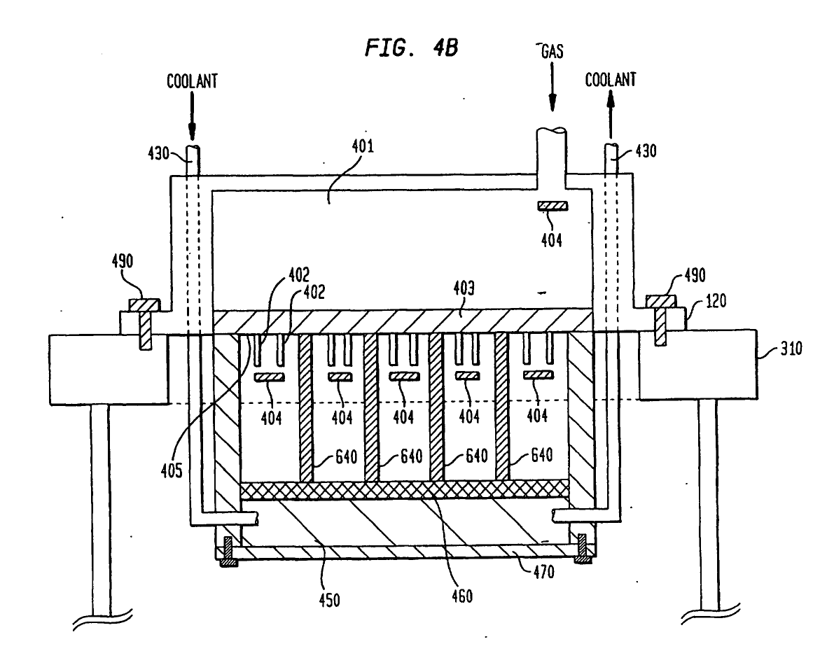

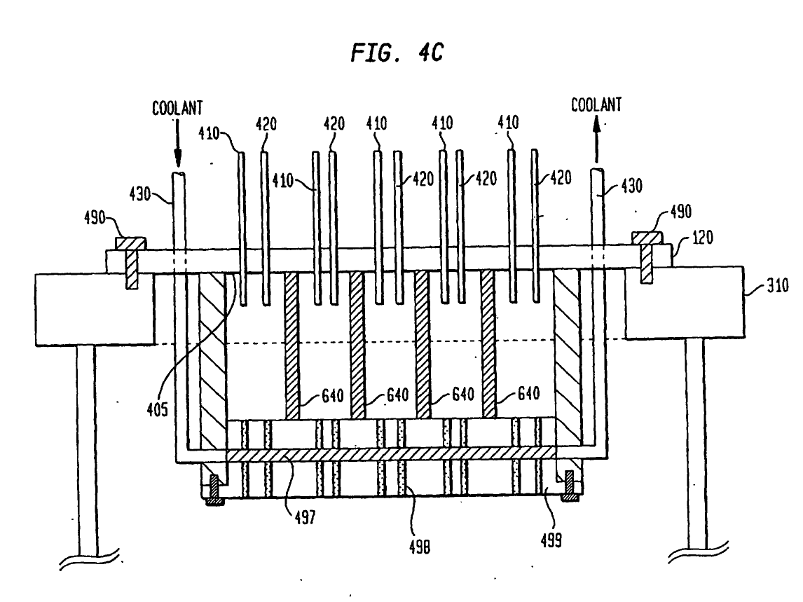

FIG. 4A schematically shows a side sectional view of an arrangement of the gas distribution system 120. The gas distribution system 120 extends through an opening in the top plate 310 of the reaction chamber 130, and is removably attached to the top plate 310 by bolts 490 or other known attachment schemes. Not shown is a vacuum sealing member, such as a deformable gasket, for providing a leak-tight seal between the top plate 310 and the gas distribution system 120.

The gas distribution system 120 includes tubes 410, 420 for delivering the deposition gas to a zone-distribution section 440 of the gas distribution system 120. Optionally, to prevent premature reaction between different reactant gases, the different reactant gases may be segregated such that the tubes 410 may be used for a first reactant gas, and the tubes 420 may be used for a second reactant gas. A set of inlet/outlet tubes 430 deliver a coolant to a cooling section 450 of the gas distribution system 120. A first flow homogenizer 460 is positioned between the zone-distribution section 440 and the cooling section 450, and a second flow homogenizer 470 is positioned below the cooling section 450 and faces the substrate holder/heater assembly 140. A manifold (not shown) divides the deposition gas delivered by the conduit assembly 160 into separate paths for connecting with the tubes 410, 420.

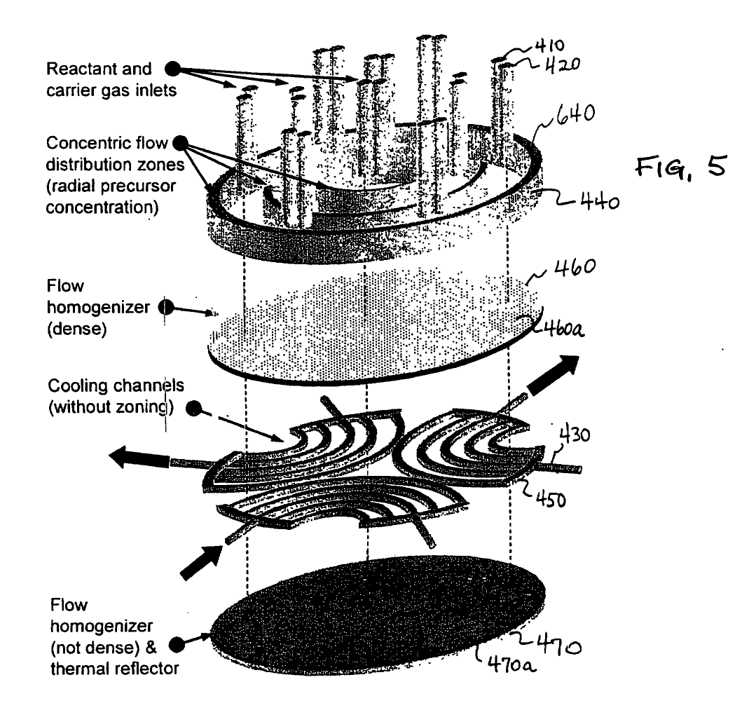

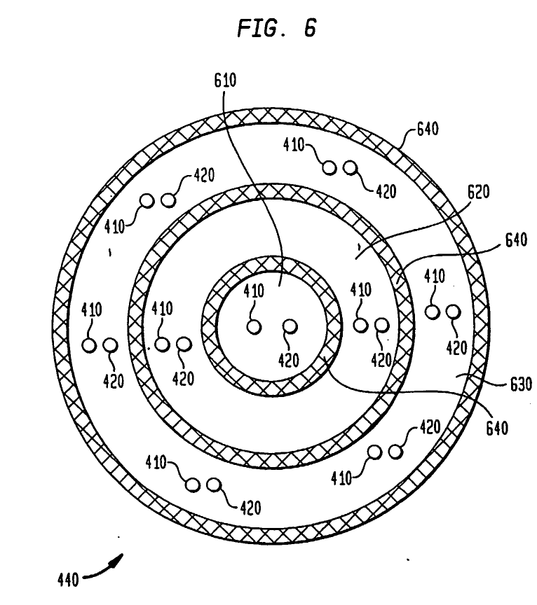

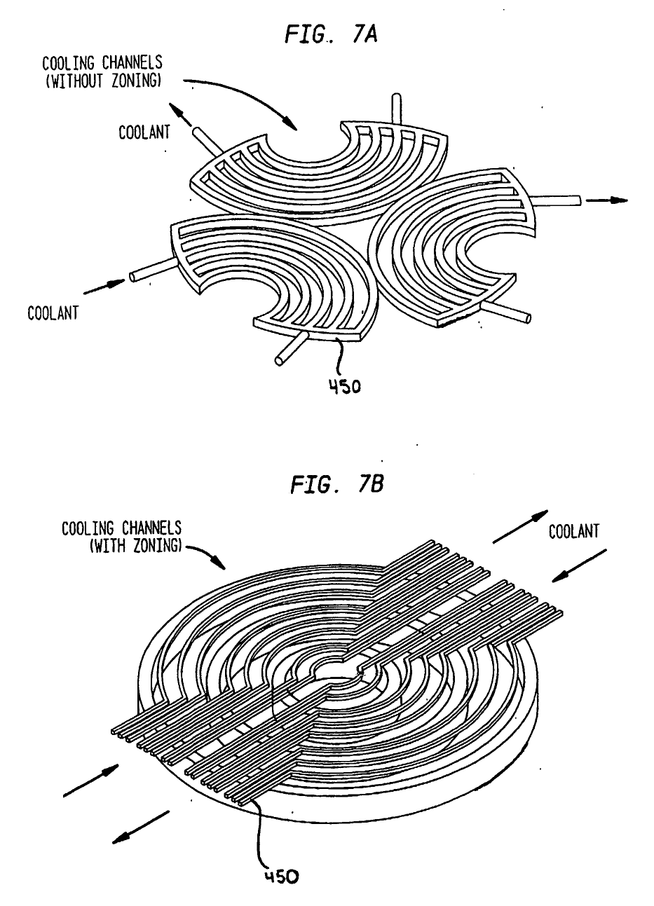

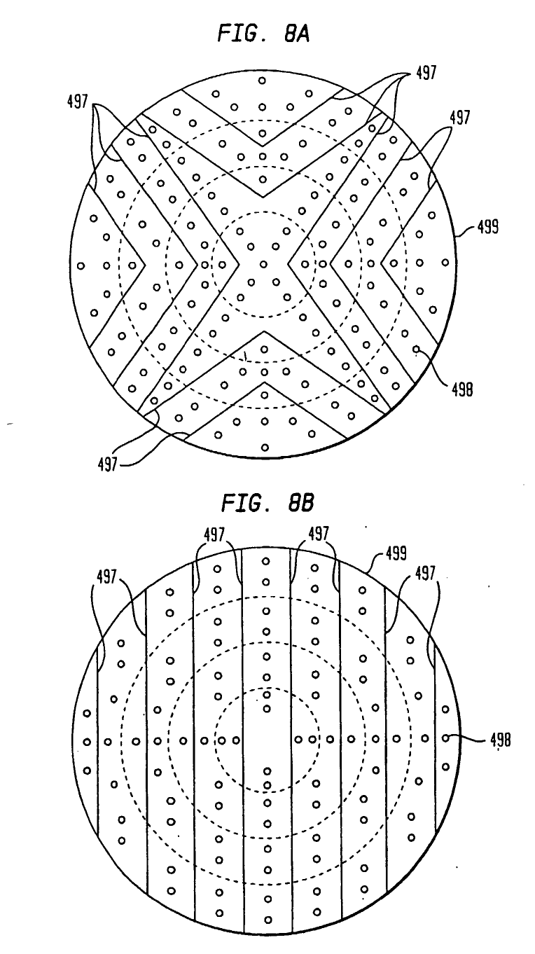

FIG. 5 schematically shows an exploded view of a portion of the gas distribution system 120, and FIG. 6 schematically shows a plan view of the zone-distribution section 440. The zone-distribution section 440 preferably is formed of multiple zones 610, 620, 630. Each of the zones 610, 620, 630 is isolated from the other zones 610, 620, 630 by baffles or walls 640, which define the zones 610, 620, 630. At least one set of tubes 410, 420 delivers the deposition gas to each zone 610, 620, 630. The number of sets of tubes 410, 420 used in each zone 610, 620, 630 increases with the area encompassed by that zone. For example, as shown in FIG. 6, a first zone 610 uses one set of tubes 410, 420; a second zone 620 having an area greater than that of the first zone 610 uses two sets of tubes 410, 420; and a third zone 630 having an area greater than that of the second zone 620 uses six sets of tubes 410, 420. Of course, the number of sets of tubes 410, 420 may vary from what is shown in FIG. 6 and, as mentioned above, is determined at least in part by the respective areas of the zones 610, 620, 630. Such an arrangement enables the amount of deposition gas distributed to various substrate areas is balanced for all areas of the substrate 320. This reduces and may even eliminate non-uniformities in thickness and/or composition, which typically occur when the deposition gas is delivered only to a central substrate area.

Preferably, the upper edges of the walls 640 of the zone-distribution section 440 accommodate a sealing device (not shown). The sealing device may be a gasket formed of, for example, copper, Viton, or a Viton-like material. Optionally, the sealing device may be a deformable metal wire made of, for example, gold, aluminum, tantalum, annealed nickel, or annealed copper. The sealing device at the upper edges of the walls 640 contact an interior wall 405 of the gas distribution system 120 and restricts the deposition gas from freely flowing across the upper edges of the walls 640.

The first flow homogenizer 460 is positioned downstream of the zone-distribution section 440 and contacts the lower edges of the walls 640, such that the reactant gas present in any of the zones 610, 620, 630 cannot flow freely to any other zone 610, 620, 630 and cannot flow freely out of the zone-distribution section 440. Optionally, the lower edges of the walls 640 accommodate a sealing device similar to that described above for the upper edges of the walls 640.

The first flow homogenizer 460 has a plurality of through-holes 460a formed therein. The reactant gas present in a zone 610, 620, 630 is forced to pass through a portion of the plurality of through-holes 460a facing that zone. This serves to homogenize the delivery of the reactant gas to the substrate 320. The first flow homogenizer 460 is made of a material that does not react with any of the gases used in film formation. Preferably, the first flow homogenizer 460 is made of a non-reactive material such as, for example, stainless steel. Optionally, the first flow homogenizer 460 may be made of a non-reactive ceramic.

The cooling section 450 is positioned downstream of and is in physical contact with the first flow homogenizer 460 and the second flow homogenizer 470. The cooling section 450 is formed of one or more tubes 710 through which a coolant flows. Preferably, the coolant is water, but other types of coolants (or even a heating fluid) may be used. As shown in FIGS. 7A and 7B, the tubes 710 may be formed into a pattern to obtain a desired cooling efficiency (FIG. 7A) or they may be formed into a zoned pattern (FIG. 7B) in which each zone 610, 620, 630 of the zone-distribution section 440 has the same or nearly the same ratio of pipe length to zone area as the other zones 610, 620, 630. The tubes 710 of the cooling section 450 are connected to the set of inlet/outlet tubes 430.

The second flow homogenizer 470 is positioned downstream of the cooling section 450 and has a plurality of through-holes 470a formed therein. The density (number per unit area) of through-holes 460a in the first flow homogenizer 460 is greater than the density of through-holes 470a in the second flow homogenizer 470. Optionally, the transparency (ratio of hole area to solid area) of the first flow homogenizer 460 is less than the transparency of the second flow homogenizer 470. Optionally, the transparency of the first flow homogenizer 460 is greater than the transparency of the second flow homogenizer 470.

The temperature of the second flow homogenizer 470 is maintained constant by the cooling section 450, even when radiatively heated by the substrate holder/heater assembly 140 during film deposition. Thus, the second flow homogenizer 470 serves as a thermal reflector for reflecting heat away from the gas distribution system 120. Optionally, one or both of a downstream surface and an upstream surface of the second flow homogenizer 470 is/are polished to efficiently reflect heat. Optionally, the second flow homogenizer 470 is formed of a ceramic or a glass, preferably transparent to infrared radiation, with a mirror-like coating on one or both of its downstream surface and its upstream surface to efficiently reflect heat. By making the upstream surface, that is, the surface facing away from the substrate holder/heater assembly 140, reflective, the second flow homogenizer 470 is able to reflect heat even if the downstream surface becomes coated with byproducts from film deposition.

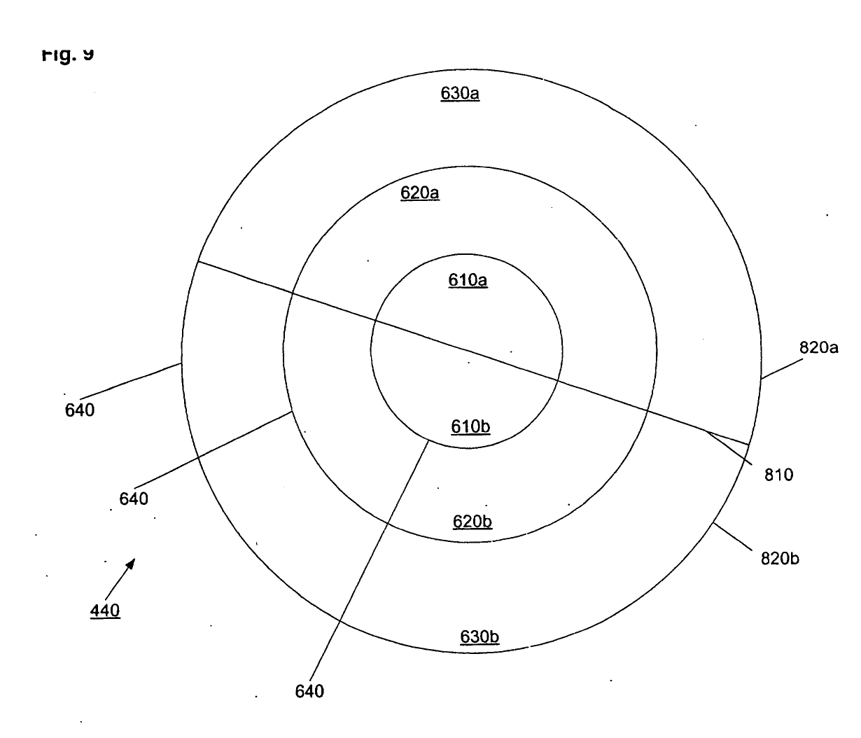

Alternatively, as shown in FIG. 9, the zone-distribution section 440 may include a separation baffle or wall 810 for dividing the zone-distribution section 440 into two halves 820a, 820b. The wall 810 functions to prevent a reactant gas delivered to the first half 820a from intermingling and prematurely forming reaction products with a reactant gas delivered to the second half 820b. Note that the tubes 410, 420 for delivering the deposition gas have been omitted from FIG. 8 for clarity. However, one of ordinary skill in the art would understand how to appropriately arrange the tubes 410, 420 so that a first reactant gas is supplied to the zone 610a, 620a, 630a of the first half 820a and a second reactant gas is supplied to the zones 610b, 620b, 630b of the second half 820b. For example, separate flash evaporators 200 may be used to provide the different reactant gases (if vaporization is necessary to form the different reactant gases). In this case, rotation of the substrate 320 by the rotatable susceptor 330 ensures that the different reactant gases are uniformly supplied to the substrate 320 during film growth.

It should be understood that the configuration of the walls 640, 810 need not be as shown in FIGS. 6 and 9, and other arrangements are within the scope of the present invention. For example, the walls 640 need not be concentric but instead may be in a grid pattern or even an irregular pattern. Also, the wall 810 need not divide the zone-distribution section 440 in half but instead may divide the zone-distribution section 440 in thirds or quarters, etc. Further, any zone or group of zones may include one or more ports for accommodating, for example, an upstream plasma tube, an optical port, etc. For example, to produce a film of doped ZnO, a first portion of the zones may be for delivering an oxidizer, a second portion of the zones may be for delivering a Zn-bearing deposition gas, and a third portion of the zones may be for delivering a dopant-bearing gas.

The zone-distribution section 440 may be disassembled for cleaning and for modifying the arrangement of the zones to achieve a desired gas distribution. Optionally, the upper and/or lower edges of the walls dividing the zones may be formed to accommodate a sealing device.

The walls 640, 810 are formed of a non-reactive material such as, for example, stainless steel.

FIG. 4B schematically shows a side sectional view of another arrangement of the gas distribution system 120. This arrangement is largely similar to the arrangement shown in FIG. 4A, except that the conduit assembly 160 delivers the deposition gas to a plenum 401. The plenum 401 distributes the deposition gas to tubes 402, which deliver the deposition gas to the zone-distribution section 440, as described above. The plenum 401 functions to uniformly distribute the flow of deposition gas out of the conduit assembly 160 to the tubes 402. A diffuser plate 403, which includes a plurality of holes, is positioned downstream from the plenum 401 and functions to establish a positive pressure from the plenum 401 to the zone-distribution section 440, such that the deposition gas flows downstream and back-diffusion is minimized. Optionally, one or more flow deflectors 404 may be positioned opposite a respective outlet of one or more of the conduit assembly 160 and the tubes 402, as shown in FIG. 4B.

FIG. 4C schematically shows a side sectional view of another arrangement of the gas distribution system 120. This arrangement is largely similar to the arrangement shown in FIG. 4A, except that the first and second flow homogenizers 460, 470 are replaced with a flow homogenizer 499 formed of a solid block of material drilled to have a plurality of through holes 498 to homogenize the reactant gas to the substrate 320. One or more cooling channels 497 are drilled in the flow homogenizer 499 through which a coolant flows. Of course, the through holes 498 and the cooling channels 497 are arranged so that they do not intersect with each other. Preferably, although not required, the flow homogenizer 499 is gun drilled to form the through holes 498 and the cooling channels 497. This avoids the presence of welds, which may crack under continuous thermal cycling and stress.

FIGS. 8A and 8B each schematically illustrate an arrangement of the flow homogenizer 499 in an overlaid representation with respect to the zone-distribution section 440, which is represented by the dotted lines. (Note that although the zone-distribution section 440 is shown to have concentric zones, it should be understood that the zones need not be concentric, as discussed above.) The cooling channels 497 are drilled such that they do not intersect with the through holes 498.

The flash MOCVD system 100 is particularly suitable for forming films of multi-component materials such as, for example, lithium niobate. A process for forming doped and undoped lithium niobate films using the flash MOCVD system 100 is described below.

The reactant gas used in film formation is produced from precursors that contain the metal(s) of interest. For example, for films of lithium niobate the metals of interest are lithium and niobium. The precursors should be sufficiently volatile such that they easily vaporize to a sufficiently high vapor pressure above the background pressure when heated above a known temperature (the volatilization temperature). The precursors also should be sufficiently stable such that they will not thermally decompose at the volatilization temperature, yet will decompose at the deposition (substrate) temperature to form a film of the desired multi-component material on the substrate 320.

In order to facilitate transfer of the precursors to the heating device 220 of the flash evaporator 200, the precursors may be dissolved in a solvent that volatilizes. The solvent should have a high solubility of the precursor. The solvent also should not react with the precursors to form any non-volatile products. Like the precursors, the solvent should have a sufficiently high vapor pressure such that the solvent fully vaporizes in the flash evaporator 200 at the conditions used for vaporizing the precursors.

Examples of precursors suitable for forming lithium niobate include niobium penta-ethoxide, which may be used as a source of niobium; lithium tert-butoxide, which may be used as a source of lithium; and titanium iso-propoxide, which may be used as a source of titanium for doping lithium niobate. Doped lithium niobate films are discussed in more detail below. Note that the examples of precursors identified above are not exhaustive, and other precursors may be used for forming lithium niobate. Preferably, the precursors are of ultra-high purity and free of Fe, although lower-purity precursors may be useful for some applications or for economic reasons.

Examples of solvents suitable for dissolving the above-identified precursors for forming lithium niobate include but are not limited to: toluene; hexane; tetrahydrofuran; and alcohols such as ethanol, isopropanol, and the like. In general, these solvents must be kept free of water and other potentially reactive species.

The solution of solvent and precursors is referred to herein as a precursor cocktail, which corresponds to the reactant material delivered to the heating device 220 discussed above. Precursor cocktails should be prepared in the absence of water to avoid pre-reaction of the precursors with water. For example, the precursor cocktails may be prepared in a moisture-free (dry) glove box. For a lithium niobate precursor cocktail, the concentration of the above-identified precursors may range from about 0.01M to about 1M. Preferably; the concentration of precursors in the precursor cocktail is in the range of about 0.05M to 0.2M. Lower concentrations may result in excessively slow film deposition rates, and concentrations that are too high may in some cases result in inefficient growth. Of course, the optimal concentration of precursors is variable and depends on the specific process conditions used for film deposition.

The feed rate of the precursor cocktail to the heater device 220 of the flash evaporator 200 may range from 0.5 to 10 cc/min for lithium niobate precursor cocktails. Preferably, the feed rate ranges from 1.2 to 2.5 cc/min. A feed rate that is too low can lead to drying of the precursor in the delivery line to the evaporation chamber 230, which can result in clogging of the line (as well as low and non-uniform film deposition rates); a feed rate that is too high can lead to pooling of the precursor cocktail at the heater device 220 due to the inability of the heater device 220 to completely volatilize the precursor cocktail at a sufficiently fast rate. This can give rise to unwanted conditions such as spitting of unvolatilized material through the delivery line, uneven back pressure in the delivery line, as well as other unwanted conditions. The delivery line generally should be selected according to the desired flow of the precursor cocktail.

Table 1 shows the ranges of deposition parameters suitable for forming lithium niobate films. Table 2 shows the preferred ranges of deposition parameters for forming lithium niobate films in a reaction chamber 130 of a particular size, and the listed flow values generally are scalable with the size of the reaction chamber 130.

TABLE 1
RANGES FOR LITHIUM NIOBATE

| | | |
|---|---|---|
| substrate temperature | 300-900° | C. |
| flash vaporization temperature of cocktail | 200-350° | C. |
| pressure of reaction chamber | 1-100 | Torr |
| Ar or N₂ (inert gas) flow rate to reaction chamber | 500-10,000 | sccm |
| O₂ (oxidant gas) flow rate to reaction chamber | 500-5000 | sccm |
| Ar or N₂ (push gas) flow rate to flash evaporator | 50-200 | sccm |
| substrate rotation speed | 500-1000 | rpm |

TABLE 2
PREFERRED RANGES FOR LITHIUM NIOBATE

| | | |
|---|---|---|
| substrate temperature | 300-625° | C. |
| flash vaporization temperature of cocktail | 230° | C. |
| pressure of reaction chamber | 5-20 | Torr |
| Ar or N₂ (inert gas) flow rate to reaction chamber | 500-3000 | sccm |
| O₂ (oxidant gas) flow rate | 1000-5000 | sccm |
| Ar or N₂ (push gas) flow rate to flash evaporator | 150-200 | sccm |
| substrate rotation speed | 750 | rpm |

At substrate temperatures less than about 450° C., the deposited lithium niobate films are amorphous. At substrate temperatures above 475° C., the deposited lithium niobate films are crystalline. The crystalline films generally are epitaxial with the underlying substrate, for substrates such as LiNbO₃, sapphire, LiTaO₃, and LaNiO₃. For substrates such as SiO₂, the deposited lithium niobate films are polycrystalline and randomly oriented.

The gases listed in Tables 1 and 2 are given as examples, and other gases may be substituted for the listed gases. That is, non-reactive or inert gases other than Ar or N₂ may be used. Similarly, H₂O, N₂O, or an alcohol such as CH₃OH, for example, may be used as an oxidant instead of O₂.

The following is a description of a process for forming lithium niobate using the flash MOCVD system 100.

SUBSTRATE AND CHAMBER PREPARATION. The substrate 320 is cleaned sufficiently to remove grease, contaminants, and particulates. The cleaning solution and protocol depend on the type of the substrate 320. For example, the substrate may be cleaned in an alkaline detergent solution, rinsed in deionized water, and degreased in isopropanol vapor. The substrate 320 is allowed to cool to room temperature before mounting onto the rotatable susceptor 330 and loading into the reaction chamber 130. The reaction chamber 130 is evacuated to a pressure of about 0.5 Torr, and the susceptor 330 of the substrate holder/heater assembly 140 is rotated to a speed of about 750 rpm. A flow of 50% Ar and 50% O₂ is introduced into the reaction chamber 130, with each gas flowing at a rate of about 500 sccm. The pressure in the reaction chamber 130 is set to about 10 Torr by a throttle valve (not shown) of the vacuum assembly 150.

PRECURSOR PREPARATION. During heating of the substrate 320, a precursor cocktail is prepared in a moisture-free, inert atmosphere in a glove box. The precursor cocktail is a solution of lithium tert-butoxide and niobium ethoxide in toluene, with a Li/Nb molar ratio of about 1 and with a total metals concentration in the toluene of about 0.05M. For example, the precursor cocktail may include approximately 56 ml of a 1.0M solution of lithium tert-butoxide, approximately 17.15 g of niobium ethoxide, and approximately 1060 ml of toluene. Note that by varying the amount of lithium tert-butoxide or varying the amount of niobium ethoxide, or both, the stoichiometry of the resulting lithium niobate film can be tailored to have electro-optical characteristics optimized for a desired application. Optionally, if titanium doping is desired to increase the refractive index of the deposited lithium niobate film, approximately 1 to 10 mole % of Ti (as a fraction of Ti+Nb) is added to the solution as titanium iso-propoxide. Typically, an amount of titanium sufficient to result in a layer having approximately 1 weight % of TiO₂ is used to make Ti-doped lithium niobate for waveguide structures. The precursor cocktail is mixed and put in one or more vessels 210, which then are sealed and brought to the reactant-gas preparation system 110.

Optionally, precursor cocktails that have been premixed to a desired prescription and properly maintained under preserving conditions may be used.

GAS PREPARATION AND DELIVERY. When the substrate 320 has reached the desired substrate temperature, as measured by an optical pyrometer (not shown) directed at the surface of the substrate 320, a solvent such as toluene is introduced to the heating device 220 of the flash evaporator 200 to clean the delivery lines of the flash evaporator 200. Of course, other solvents may be used for this purpose. The evaporation chamber 230 is isolated from the reaction chamber 130 during vaporization of the solvent, and the vaporized solvent is vented through the vacuum pump 270. Then, the precursor cocktail in the vessel 210 is introduced to the heating device 220 and the flow of the solvent is shut off. An inert push gas is delivered to the evaporation chamber at a flow rate of about 50 to 500 sccm. The feed rate of the precursor cocktail to the heating device 220 is about 2 to 2.5 ml/min, and preferably is about 2 ml/min. After the precursor cocktail has been vaporizing for approximately 30 seconds, the vaporized gas (i.e., the reactant gas) is delivered to the reaction chamber 130 via the conduit assembly 160 and the gas distribution system 120, and the venting of the reactant gas by the vacuum pump 270 ceases.

DEPOSITION AND POST-DEPOSITION PROCEDURE. During deposition, the pressure in the reaction chamber 130 and the back-pressure in the evaporation chamber 230 is monitored and periodically recorded. If more than one vessel 210 is used, when the precursor cocktail in one of the vessels 210 is consumed, the precursor cocktail in another of the vessels 210 is used. When the desired amount of the precursor cocktail has been consumed (i.e., the desired amount being an amount that will result in the desired film thickness), film deposition ends and the reaction chamber 130 and the substrate 320 are allowed to cool to room temperature. Rotation of the substrate 320 is reduced to zero. The reaction chamber 130 is vented to atmospheric pressure with air or an inert gas such as Ar. The substrate 320 then is removed from the reaction chamber 130. The thickness of the deposited film typically is approximately 1.6 μm for the precursor cocktail prepared as indicated above.

### EXAMPLE 1

### Amorphous Lithium Niobate Films

Lithium niobate films grown at a substrate temperature of less than about 450° C. and preferably less than about 425° C. are amorphous and easily etched in a solution of 5% HF or by reactive-ion etching or by ion milling. This makes amorphous lithium niobate films particularly suitable for lithographic patterning into fine structures or devices. The precursor cocktail is prepared as described above. Typical deposition parameters for forming amorphous lithium niobate are summarized in Table 3.

TABLE 3
AMORPHOUS LITHIUM NIOBATE

| | | |
|---|---|---|
| substrate temperature | 300-425° | C. |
| flash vaporization temperature of cocktail | 230° | C. |
| pressure of reaction chamber | 10 | Torr |
| Ar or N₂ (inert gas) flow rate to reaction chamber | 500 | sccm |
| O₂ (oxidant gas) flow rate to reaction chamber | 3000 | sccm |
| Ar or N₂ (push gas) flow rate to flash evaporator | 200 | sccm |
| substrate rotation speed | 750 | rpm |

For a feed rate of the precursor cocktail of about 1 ml/min, the growth rate of amorphous lithium niobate films is approximately 0.2 μ/h. Amorphous films deposited according to the above conditions may be crystallized by annealing in oxygen at 1000° C. for about 1 h.

### EXAMPLE 2

### Mixed-Phase Lithium Niobate Films

Lithium niobate films grown at a substrate temperature of approximately 450° C. have microcrystalline regions in an amorphous matrix. These mixed-phase films are easily etched in a solution of 5% HF but do not yield uniform sidewall profiles when lithographically patterned. This likely is due to the different etch rates of the microcrystalline regions and the amorphous matrix.

The deposition parameters for forming mixed-phase lithium-niobate films may be as shown in Table 1, 2, or 3, except for the deposition (substrate) temperature. For a feed rate of the precursor cocktail of about 1 m/min, the growth rate of mixed-phase films is approximately 0.6 μm/h.

### EXAMPLE 3

### Crystalline Lithium Niobate Films

Lithium niobate films grown at a substrate temperature above 475° C. are crystalline. The growth rate is strongly dependent on the substrate temperature and may vary from approximately 0.9 μm/h at 475° C. to approximately 1.8 μm/h at 500° C. to approximately 3.0 μm/h at 625° C., for a feed rate of the precursor cocktail of about 1 ml/min. In comparison, conventional methods for forming crystalline lithium niobate films have a reported deposition rate of only about 100 nm/h at 640° C. and only about 150 nm/h at 700° C. Therefore, the present invention provides a system and a method for depositing lithium niobate films at a deposition rate that is over an order of magnitude greater than that of conventional methods, at comparable deposition temperatures.

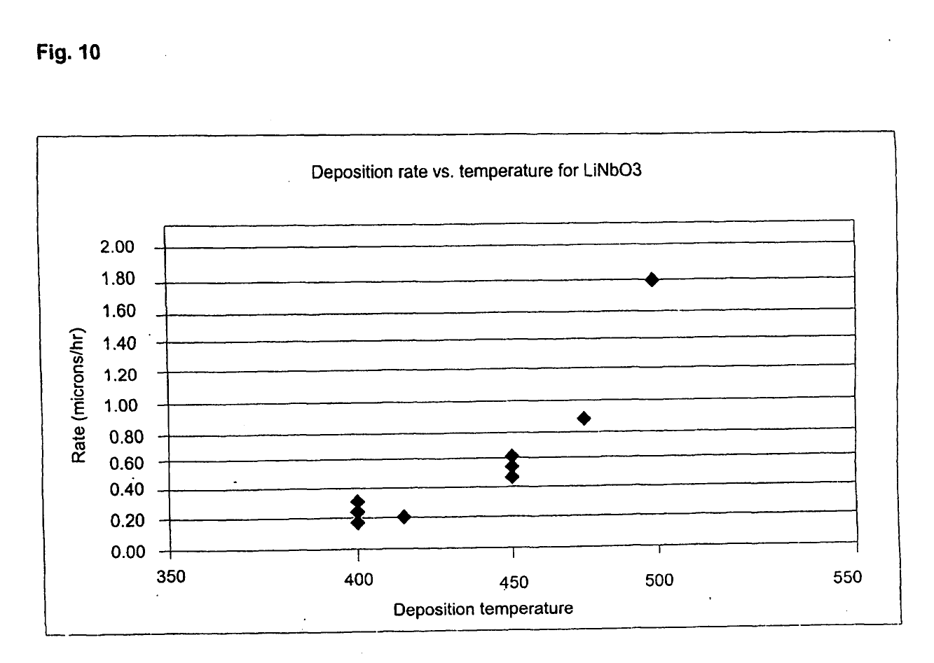

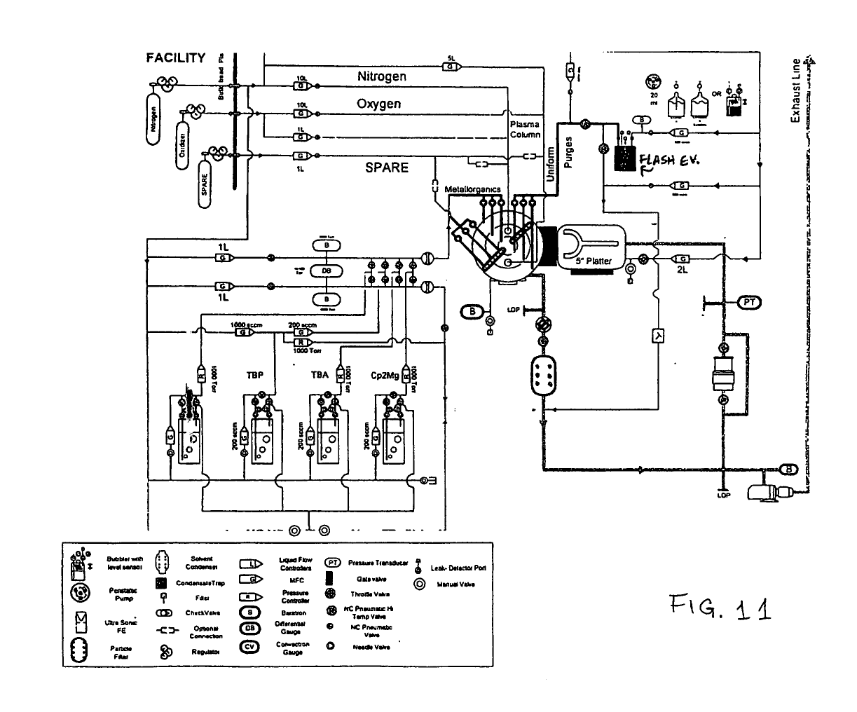

FIG. 10 is a graph showing how the deposition rate of lithium niobate varies as a function of the deposition (substrate) temperature, for temperatures up to 500° C. and for a fixed feed rate of the precursor cocktail.

The deposition parameters for forming crystalline lithium-niobate films may be as shown in Table 1, 2, or 3, except for the deposition (substrate) temperature.

The crystallinity of the lithium niobate films depends on the type of substrate used as well as on the deposition temperature. On amorphous substrates such oxidized silicon, polycrystalline films are formed. On single-crystal substrates of lithium niobate, the deposited lithium niobate films grow epitaxially with the substrate. That is, the deposited films predominantly are single crystalline and take on the orientation of the underlying substrate. Similarly, single crystalline sapphire substrates yield highly oriented lithium niobate films that predominantly are single crystalline.

As discussed above, it often is desirable to dope lithium niobate to tailor its properties for specific applications. For example, lithium niobate doped with Ti has a higher index of refraction than undoped lithium niobate films, and thus may be used for waveguiding applications. At a solubility of TiO₂ in lithium niobate of about 8%, a change in index (An) of about 0.012 is achievable. Table 4 lists various dopants for lithium niobate, their corresponding precursors, as well as the properties of the doped material.

TABLE 4
DOPANTS FOR LITHIUM NIOBATE

| METAL | PRECURSOR | APPLICATIONS/PROPERTIES |
|---|---|---|
| titanium | titanium iso-propoxide | waveguides (changes index of |
| | | refraction) |
| magnesium | bis-cyclopentadienyl | improving resistance to optical |
| | magnesium | damage |
| tantalum | tantalum ethoxide | tuning electro-optical properties |
| erbium (or | Er(thd)₃ (tris-2,6- | lasers |
| other rare | tetramethyl-3,5- | |
| earths) | heptanedionato erbium) | |

Doped lithium niobate films may be formed as described above, using a precursor cocktail that includes a suitable precursor for the desired dopant, i.e., a precursor that has volatility and stability characteristics that are compatible with the precursors for forming undoped lithium niobate.

The flash MOCVD system 100 may be used to deposit films of zinc oxide (ZnO), which has a bandgap in the 3.4 eV range, thus making it attractive for blue and violet light-emitting diodes and lasers. Preferably, diethyl zinc is used as the precursor for zinc, and the oxidant preferably is O₂. The diethyl zinc is volatilized from a bubbler source, typically, or alternatively in the flash evaporator 200, and the volatilized precursor and the oxidant are delivered to the gas distribution system 120 as described above.

Doping of ZnO to form n-type material may be achieved using elemental dopants that act as electron donors when substituting for Zn atoms, such as In, Ga, Al, or B, or elemental dopants that act as electron donors when substituting for O atoms, such as F or Cl. Examples of n-type dopant precursors for ZnO include trimethyl indium as the precursor for In; trimethyl gallium as the precursor for Ga; and trimethyl aluminum as the precursor for Al.

Doping of ZnO to form p-type material may be achieved using elemental dopants that act as electron acceptors when substituting for Zn atoms, such as Cu, Ag, Li, Na, or K, or elemental dopants that act as electron acceptors when substituting for O atoms, such as N, P, As, or Sb. Examples of p-type dopant precursors for ZnO include N₂ or N₂O gases. Table 5 shows data illustrating the effect of changes in the dopant concentration on the as-deposited electrical properties of doped ZnO. Post-deposition annealing removes hydrogen from as-deposited ZnO and strengthens or enhances the p-type characteristics of ZnO. Alloying ZnO with CdO or MgO may be done to decrease or increase, respectively, the bandgap of ZnO films. Examples of precursors for bandgap engineering of ZnO films include bis-cyclopentadienyl magnesium as the precursor for Mg and dimethyl cadmium as the precursor for Cd.

TABLE 5
ZINC OXIDE DOPING RESULTS

| | | SHEET | |
|---|---|---|---|
| | DOPING | RESIS- | |
| RUN | PUSH FLOW | TIVITY | HALL-MEASUREMENT |
| NO. | (sccm) | (Ωcm) | RESULTS |
| 1 | 500 | 0.363 | n-type; n = 1.33 × 10¹⁸ cm⁻³; |
| | | | μ = 13 cm²/Vs |
| 2 | 300 | 0.35 | n-type; n = 1.6 × 10¹⁸ cm⁻³; |
| | | | μ = 11 cm²/Vs |
| 3 | 250 | 3.01 | n-type; n = 1.16 × 10¹⁷ cm⁻³; |
| | | | μ = 18 cm²/Vs |
| 4 | 125 | 12.5 | n-type; n = 1.78 × 10¹⁶ cm⁻³; |
| | | | μ = 28 cm²/Vs |
| 5 | 35 | 325 | p-type; n = 3.2 × 10¹⁵ cm⁻³; |
| | | | μ = 6 cm²/Vs |
| 6 | 35 | 4.416 | p-type; n = 7.9 × 10¹⁵ cm⁻³; |
| | | | μ = 175 cm²/Vs |

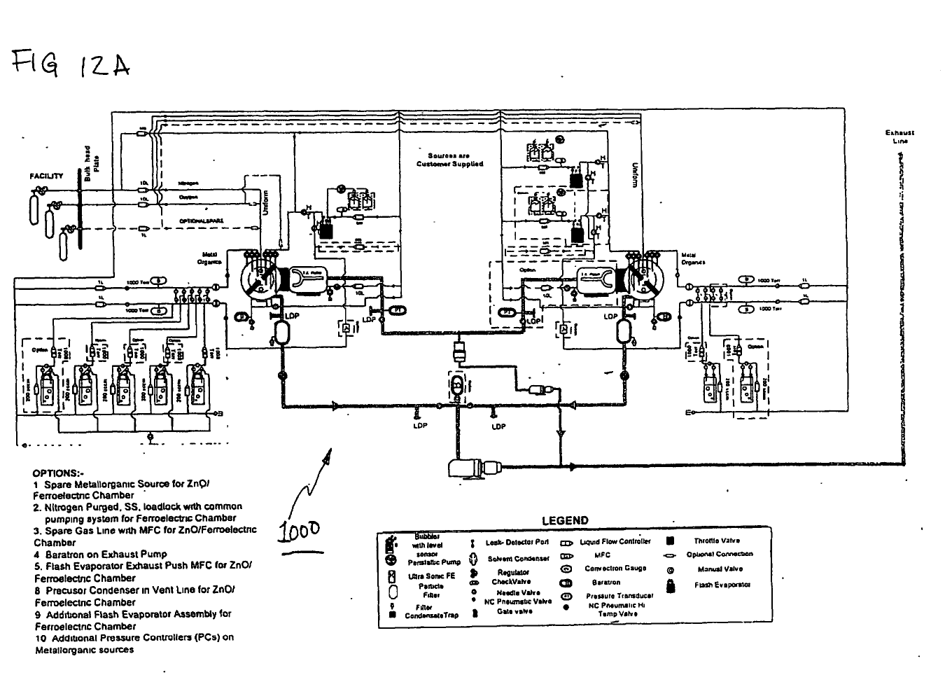

An arrangement of a system for depositing ZnO (doped and undoped) is schematically shown in FIG. 11.

A layered structure of p-type ZnO and n-type ZnO (i.e., a pn junction) may be produced in situ by, for example, depositing the n-type ZnO layer first, then changing from an n-type dopant source to a p-type dopant source, and then continuing the deposition process using the p-type dopant source to form the p-type ZnO layer. This can be accomplished using a single flash evaporator 200 with a vessel 210 containing a precursor cocktail for the p-type ZnO layer and another vessel 210 containing a precursor cocktail for the n-type ZnO layer. Alternatively, bubblers alone may be used for providing the precursors for the ZnO layers. The use of a single flash evaporator 200, however, presents a possible problem of proper removal of all of the dopant of the first layer from the delivery lines and the reaction chamber 130 before depositing the second layer.

Alternatively, in situ formation of the layered structure can be accomplished using two flash evaporators 200; one flash evaporator 200 dedicated for the p-type doping and the other flash evaporator 200 dedicated for the n-type doping. This alternative, however, presents a possible problem of proper removal of all of the dopant of the first layer from the reaction chamber 130 before depositing the second layer. For some dopants, the “memory effect” is significant and results in the incorporation of previously used dopants into films deposited long after those dopants have stopped being used.

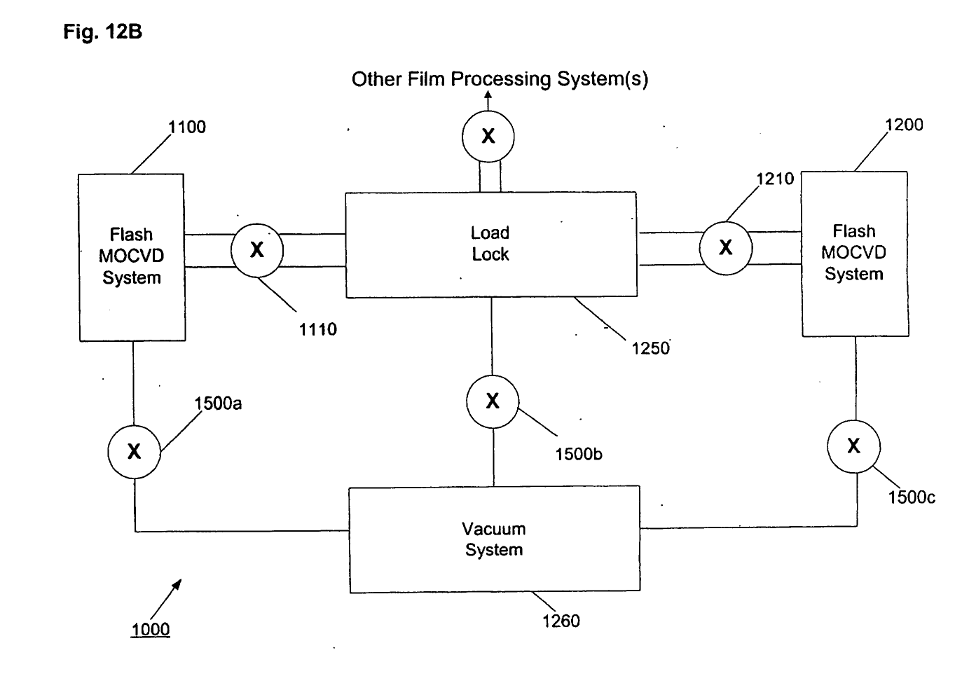

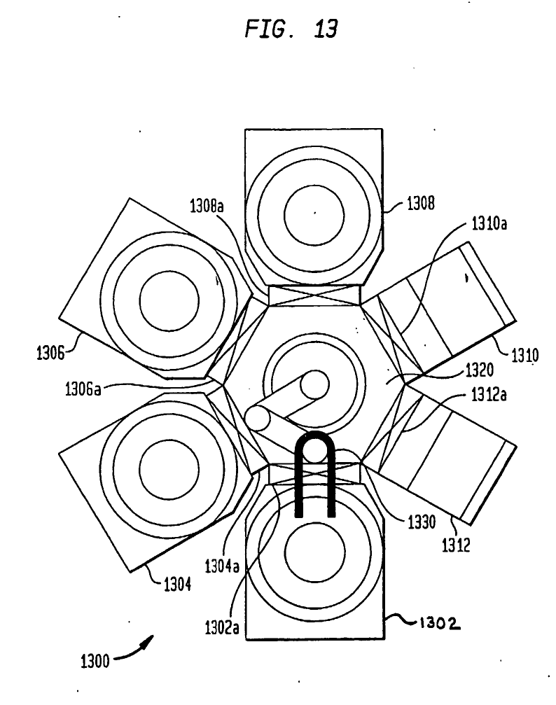

To remedy the “memory effect” problem, a multiple-chamber MOCVD system may be used. FIG. 12A schematically shows a multi-flash MOCVD system 1000 according to an embodiment of the present invention, and FIG. 12B shows a block diagram of selected features of the multi-flash MOCVD system 1000.

The multi-flash MOCVD system 1000 includes a first flash MOCVD system 1100 and a second flash MOCVD system 1200. Each of the flash MOCVD systems 1100, 1200 is a flash MOCVD system 100 as described above. The flash MOCVD systems 1100, 1200 are interconnected by a load-lock system 1250, which functions to load a substrate into the multi-flash MOCVD system 1000 and to transport the substrate between the first flash MOCVD system 1100 and the second flash MOCVD system 1200.

The load-lock system 1250 utilizes known techniques for loading and unloading the substrate into the multi-flash MOCVD system 1000 and for transporting the substrate within the multi-flash MOCVD system 1000. For example, the load-lock system 1250 may include a substrate grasping unit (not shown), which selectively extends into one of the first or the second flash MOCVD system 1100, 1200 to grasp the substrate and either transport the substrate to the other flash MOCVD system 1100, 1200 or unload the substrate via the load-lock system 1250.

Gate valves 1110, 1210 are positioned to isolate the first and second flash MOCVD systems 1100, 1200 from the load-lock system 1250. A vacuum system 1260 is connected to the first and second flash MOCVD systems 1100, 1200 as well as the load-lock system 1250. Valves 1500a, 1500b, 1500c are positioned to isolate any or all of the first and second flash MOCVD systems 1100, 1200 and the load-lock system from the vacuum system 1260.

Although the multi-flash MOCVD system 1000 shown in FIGS. 12A and 12B show only two deposition chambers and is an example of a multiple-chamber MOCVD system of the present invention, one of ordinary skill in the art will appreciate that the multiple-chamber MOCVD system of the present invention may include one or more flash MOCVD systems 100 as well as one or more of a sputtering system, an evaporation system, a molecular-beam epitaxy system, a conventional CVD system, an annealing system, a plasma treatment system, an ion milling system, and an etching system. The multiple chambers are interconnected via a load-lock system and may be arranged as a cluster around the load-lock system.

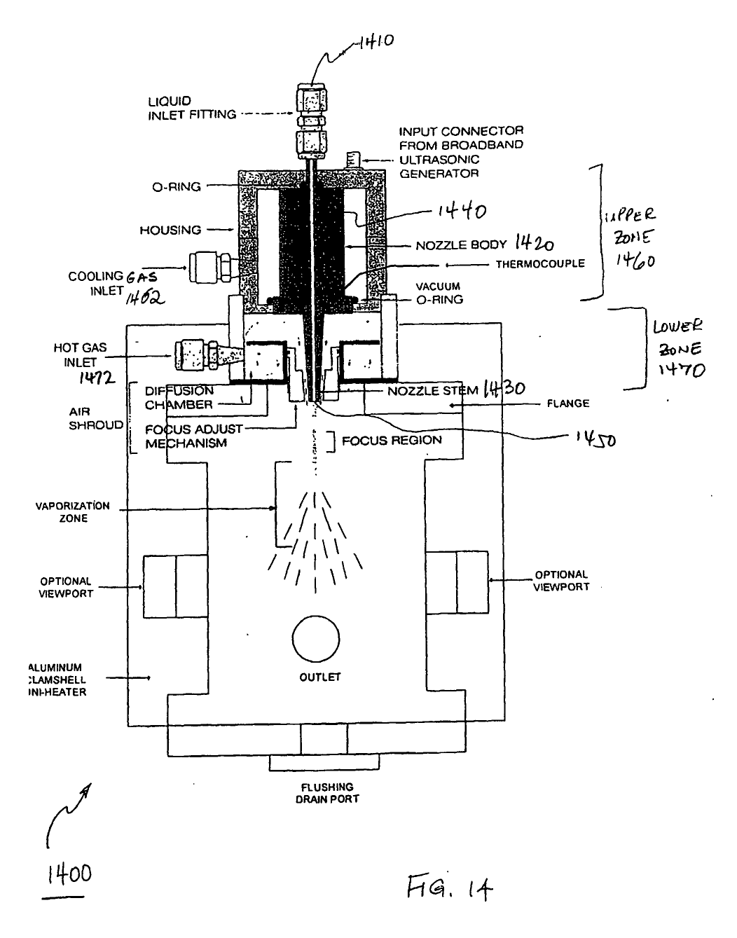

FIG. 13 schematically depicts an exemplary multiple-chamber deposition system 1300 arranged in a cluster, according to an embodiment of the present invention. The system 1300 includes a plurality of chambers 1302, 1304, 1306, 1308, 1310, 1312, arranged around and interconnected to a load-lock system 1320. The plurality of chambers may include one or more of a flash MOCVD system 100, a sputtering system, an evaporation system, a molecular-beam epitaxy system, a conventional CVD system, an annealing system, a plasma-treatment system, and the like. Although any of the plurality of chambers may be used for annealing, it is preferable to have a separate annealing system to minimize cross contamination and to increase throughput.

The load-lock system 1320 includes a substrate grasping unit 1330, which selectively extends into any of the chambers 1302, 1304, 1306, 1308, 1310, 1312 to grasp a substrate and either transport the substrate to another chamber 1302, 1304, 1306, 1308, 1310, 1312 or unload the substrate via the load-lock system 1320. Gate valves 1302a, 1304a, 1306a, 1308a, 1310a, 1312a are respectively positioned to isolate the plurality of chambers 1302, 1304, 1306, 1308, 1310, 1312 from the load-lock system 1320.

Although the multiple-chamber deposition system 1300 schematically shown in FIG. 13 is depicted with six chambers, optionally it may have a number of chambers other than six. Also although the multiple-chamber deposition system 1300 is shown in a cluster or star-like configuration, other configurations are within the scope of the present invention, such as a linear configuration, for example.

As will be appreciated by one of ordinary skill in the art, the multi-flash MOCVD system 1000 and the multiple-chamber deposition system 1300 of the present invention enables a multi-layer structure to be deposited and processed in situ, i.e., without exposing any layer or interface in the structure to atmospheric conditions and without cross contamination of any of the multiple chambers. For example, a layer may be formed by MOCVD in a first chamber, annealed in a second chamber, coated with a passivation layer or a metallization layer in a third chamber, treated with a plasma in a fourth chamber, etc., all within the same system. This enables, for example, pn junctions, p-i-n junctions, heterostructures, structures with buffer layers, etc., to be formed in situ.

While the present invention has been described with respect to what is considered to be the preferred embodiments, it is to be understood that the invention is not limited to the disclosed embodiments. To the contrary, the invention is intended to cover various modifications and equivalent arrangements included within the spirit and scope of the appended claims. The scope of the following claims is to be accorded the broadest interpretation so as to encompass all such modifications and equivalent structures and functions.

For example, although the above description focuses on lithium niobate and ZnO, the system of the present invention may be used to produce films of other oxides (conductive or dielectric), silicides, nitrides, alloys, metals, insulators, semiconductors, etc.

As will be appreciated, there are countless other configurations for the arrangements shown in the drawings, and in no way should it be construed that the present invention is limited the arrangements as shown.

Additionally, it is to be understood that features that are indicated to be preferred are not to be construed to be required features.

What is claimed is:

1. A flash MOCVD system, comprising:
a reaction chamber;
a substrate assembly positioned within the reaction chamber;
a flash evaporator for vaporizing a reactant material to form a reactant gas;
a gas distribution system for uniformly distributing the reactant gas to the substrate assembly.

2. A flash MOCVD system according to claim 1, wherein the flash evaporator vaporizes the reactant material by heating the reactant material.

3. A flash MOCVD system according to claim 1, wherein the flash evaporator ultrasonically vaporizes the reactant material.

4. A flash MOCVD system according to claim 1, wherein
the reactant material is comprised of a solution of at least one precursor and a solvent, and
the flash evaporator vaporizes the solution to form the reactant gas.

5. A flash MOCVD system according to claim 1, wherein the flash evaporator comprises:
a vessel for containing a liquid precursor solution;
an evaporation chamber;
a heating device arranged in the evaporation chamber; and
a pump for providing a controlled flow of the liquid precursor solution to the heating device in the evaporation chamber.

6. A flash MOCVD system according to claim 5, wherein the flash evaporator is continuously isolated from atmospheric conditions to prevent water vapor from condensing on internal surfaces thereof.

7. A flash MOCVD system according to claim 5, wherein the evaporation chamber is maintained at an elevated temperature to prevent water vapor from condensing on internal surfaces thereof.

8. A flash MOCVD system according to claim 1,
wherein the flash evaporator is an ultrasonic flash evaporator comprising:
a nozzle formed of a nozzle body and a nozzle stem;
a cooling device arranged to maintain a temperature of the nozzle body below a Curie temperature of piezoelectric material in the nozzle;
a heating device arranged to maintain a temperature of the nozzle stem above a temperature at which liquid condenses on the nozzle stem and but below the Curie temperature of the piezoelectric material in the nozzle, and
wherein the reactant material passes through the nozzle and is vaporized by ultrasonic waves launched through the nozzle, such that as the reactant material exits the nozzle stem the ultrasonic waves vaporize the reactant material to form the reactant gas.

9. A flash MOCVD system according to claim 1,
wherein the gas distribution system comprises:
a zone-distribution section arranged to respectively confine a plurality of quantities of the reactant gas to a plurality of zones;
a first flow homogenizer positioned downstream of the zone-distribution section, wherein the first flow homogenizer is formed with a plurality of through-holes therein;
a cooling section positioned downstream of the first flow homogenizer, wherein the cooling section is comprised of one or more pipes through which a coolant flows;
a second flow homogenizer positioned downstream of the cooling section, wherein the second flow homogenizer is formed with a plurality of through holes therein,
wherein the cooling section is in physical contact with the first and second flow homogenizers,
wherein a density of through-holes in the first flow homogenizer is greater than a density of through-holes in the second flow homogenizer, and
wherein the quantities of the reactant gas respectively confined in the plurality of zones varies with a respective volume of the plurality of zones.

10. A flash MOCVD system according to claim 9,
wherein the zone-distribution section is formed with walls,
wherein each of the walls contacts an interior surface of the reaction chamber via a sealing device, which prevents the reactant gas from freely flowing between the plurality of zones through one or more openings between the zone-distribution section and the walls.

11. A flash MOCVD system according to claim 9, wherein the plurality of zones is concentric.

12. A flash MOCVD system according to claim 10,
wherein the walls of the zone-distribution section include a wall bisecting the zone-distribution section into a first half and a second half, such that each zone of the plurality of zones is bisected,
wherein the reactant gas is comprised of a first gas and a second gas,
wherein the first gas is delivered to the first half of the zone-distribution section and the second gas is delivered to the second half of the zone-distribution section.

13. A flash MOCVD system according to claim 12, wherein the substrate assembly is configured to rotate a substrate mounted thereon.

14. A flash MOCVD system according to claim 9, wherein the one or more pipes of the cooling section are arranged according to the plurality of zones.

15. A flash MOCVD system according to claim 9, wherein a transparency of the first flow homogenizer is different from a transparency of the second flow homogenizer.

16. A flash MOCVD system according to claim 9, wherein the second flow homogenizer reflects heat from the substrate assembly away from the gas distribution system.

17. A flash MOCVD system according to claim 9,
wherein the gas distribution system further comprises:
a plenum positioned upstream from the zone-distribution section; and
a diffuser plate positioned downstream from the plenum and upstream from the zone-distribution section, wherein the diffuser plate is formed with a plurality of holes therein, and
wherein the plenum maintains a higher pressure of the reactant gas relative to a pressure of the reactant gas in the zone-distribution section.

18. A flash MOCVD system according to claim 9, wherein the second flow homogenizer
is formed of a material that is transparent to infrared radiation,
has a first surface facing the substrate assembly and a second surface opposite the first surface, and
has a reflective coating formed on the second surface to enable the second flow homogenizer to reflect heat regardless of a condition of the first surface.

19. A flash MOCVD system according to claim 1, wherein the substrate assembly includes a heater for heating a substrate mounted thereon.

20. A flash MOCVD system according to claim 1, wherein the substrate assembly is configured to cool a substrate mounted thereon.

21. A flash MOCVD system according to claim 1, wherein the system is configured to form films of lithium niobate having a stoichiometric composition.

22. A flash MOCVD system according to claim 1, wherein the system is configured to form films of lithium niobate having a non-stoichiometric composition.

23. A flash MOCVD system according to claim 21 or claim 22, wherein the system is configured to form doped films of lithium niobate.

24. A flash MOCVD system according to claim 21 or claim 22, wherein the gas distribution system controls film uniformity.

25. A flash MOCVD system according to claim 24, wherein a lithium niobate film deposited on a substrate by the system is uniform in thickness and composition over an entire surface of the substrate.

26. A flash MOCVD system according to claim 1, wherein the system is configured to produce lithium niobate films with crystallinity ranging from amorphous to polycrystalline to highly oriented to epitaxial, and combinations thereof.

27. A multiple-chamber MOCVD system, comprising:
at least two flash MOCVD systems, wherein each flash MOCVD is a flash MOCVD system according to claim 1; and
a load-lock system interconnecting the at least two flash MOCVD systems.

28. A multiple-chamber MOCVD system, comprising:
a flash MOCVD system according to claim 1;
a film deposition system different from the flash MOCVD system; and
a load-lock system interconnecting the flash MOCVD system and the film deposition system.

29. A multiple-chamber MOCVD system according to claim 27 or claim 28, wherein the multiple-chamber MOCVD system is configured to form films of ZnO.

30. A multiple-chamber MOCVD system according to claim 27 or claim 28,
wherein the multiple-chamber MOCVD system is configured to form a multi-layer structure having a pn junction, and
wherein the multi-layer structure is formed without exposing an interface of the pn junction to atmospheric conditions.

31. A multiple-chamber MOCVD system according to claim 27 or claim 28, further comprising an annealing system connected to the load-lock system.

32. A multiple-chamber MOCVD system according to claim 27 or claim 28, wherein the system is configured to form in situ a film of p-type ZnO, to anneal the film of p-type ZnO, and to form a film of n-type ZnO above the film of p-type ZnO.

33. A multiple-chamber MOCVD system according to claim 32, wherein the multi-layer structure includes a p-type ZnO layer and an n-type ZnO layer.

34. A multiple-chamber MOCVD system according to claim 27 or claim 28,
wherein the multiple-chamber MOCVD system is configured to form a multi-layer structure in which at least one layer is undoped lithium niobate and in which at least one layer is doped lithium niobate.

35. A flash MOCVD system according to claim 1,
wherein the flash MOCVD system includes a plurality of flash evaporators, and
wherein each of the plurality of flash evaporators produces a different reactant gas.

36. A process for forming lithium niobate by MOCVD, the process comprising the steps of:
preparing a precursor solution containing at least a Li-bearing precursor, a Nb-bearing precursor, and a solvent;
using a flash evaporator to vaporize the solution to produce a reactant gas;
delivering the reactant gas to a heated substrate; and
decomposing the reactant gas on the substrate to deposit a crack-free film of lithium niobate greater that 1.5 μm in thickness.

37. A process according to claim 36, wherein the solvent is delivered to the flash evaporator at a feed rate between about 0.5 to 10 cc/min.

38. A process according to claim 36, wherein the solvent is delivered to the flash evaporator at a feed rate between about 1.3 to 2.5 cc/min.

39. A process according to claim 36, wherein the flash evaporator vaporizes the solution using heat.

40. A process according to claim 36, wherein the flash evaporator vaporizes the solution using ultrasonic waves.

41. A process according to claim 36, wherein the film of lithium niobate is stoichiometric.

42. A process according to claim 36, wherein the film of lithium niobate is non-stoichiometric.

43. A process according to claim 36, wherein the film of lithium niobate is doped.

44. A process according to claim 36, wherein the film of lithium niobate is amorphous.

45. A process according to claim 36, wherein the film of lithium niobate is crystalline.

46. A process according to claim 36, wherein the step of decomposing the reactant gas results in a film deposition rate greater than 0.2 μm/h.

47. A process according to claim 36, wherein the step of decomposing the reactant gas results in a film deposition rate of approximately 3 μm/h or greater.

48. A process according to claim 36, wherein the substrate is heated to a temperature of approximately 625° C. or greater.

49. A process according to claim 36, wherein the substrate is heated to a temperature of approximately 400° C. or greater.

50. A lithium niobate film formed according to the process of claim 36.

51. A lithium niobate film according to claim 50, wherein the lithium niobate film is an optical coating.

52. A process according to claim 36, wherein the film of lithium niobate has a first index of refraction, and the substrate has a second index of refraction different from the first index of refraction.

53. A process for forming a film by MOCVD, the process comprising the steps of:
preparing a precursor solution containing at least a precursor land a solvent;
using a flash evaporator to vaporize the solution to produce a reactant gas;
delivering the reactant gas to a heated substrate; and
decomposing the reactant gas on the substrate to deposit a crack-free film.

54. A process according to claim 53, wherein the substrate is lithium niobate.

55. A process according to claim 53, wherein the film is a metal oxide.

56. A process according to claim 55, wherein the metal oxide is conductive.

57. A process according to claim 53, wherein the film is a metal.

58. A process according to claim 53, wherein the film is an insulator.

59. A flash MOCVD system according to claim 1,
wherein the gas distribution system comprises:
a zone-distribution section arranged to respectively confine a plurality of quantities of the reactant gas to a plurality of zones; and
a flow homogenizer positioned downstream of the zone-distribution section, wherein the flow homogenizer is formed with a plurality of through-holes therein through which the reactant gas passes, and wherein the flow homogenizer is formed with one or more conduits therein through which a coolant passes, and
wherein the plurality of through holes do not intersect with the one or more conduits.

60. A flash MOCVD system according to claim 59, wherein the plurality of through holes and the one or more conduits are formed by drilling the flow homogenizer.

61. A process for forming a pn junction, comprising the steps of:
using a first chamber of a multi-chamber deposition system to grow a film of ZnO;
transporting the film of ZnO to a second chamber of the multi-chamber deposition system without exposing the film of ZnO to atmospheric conditions; and
using the second chamber of the multi-chamber deposition system to anneal the film of ZnO.

62. A process according to claim 61, wherein the film of ZnO is insulating prior to being annealed, and wherein the film of ZnO has a p-type conductivity after being annealed.

63. A process according to claim 62, further comprising the steps of:
transporting the annealed film of ZnO to a third chamber of the multi-chamber deposition system without exposing the annealed film of ZnO to atmospheric conditions; and
using the third chamber of the multi-chamber deposition system to deposit a second film of ZnO.

64. A process according to claim 63, wherein the second film of ZnO has an n-type conductivity.

65. A process according to claim 63 or claim 64, further comprising the steps of:
transporting the second film of ZnO to the second chamber or to a fourth chamber of the multi-chamber deposition system without exposing the second film of ZnO to atmospheric conditions; and
using the second chamber or the fourth chamber of the multi-chamber deposition system to anneal the second film of ZnO.

66. A process according to claim 63 or claim 64, further comprising the steps of:
transporting the second film of ZnO to a fourth chamber of the multi-chamber deposition system without exposing the second film of ZnO to atmospheric conditions; and
using the fourth chamber of the multi-chamber deposition system to form a passivation layer or a metallization layer above the second film of ZnO.

67. A process according to claim 62, wherein the film of ZnO is doped with N.

68. A process according to claim 62, wherein hydrogen is removed from the ZnO film when the ZnO film is annealed using the second chamber of the multi-chamber deposition system.

69. A process according to claim 64, further comprising the step of using a fourth chamber of the multi-chamber deposition system to deposit an insulating film prior to depositing the second film of ZnO using the third chamber of the multi-chamber deposition system.

70. A process according to claim 64, wherein at least one of the first film of ZnO and the second film of ZnO is deposited with an alloying element to affect a bandgap of the film or films of ZnO.
